(19) United States
(12) Patent Application Publication
(10) Pub. No.: US 2026/0297988 A1
(43) Pub. Date: Oct. 1, 2026

(54) REAL-TIME PARAMETER BASED OBSTACLE DETECTION

(71) Applicant: GM GLOBAL TECHNOLOGY OPERATIONS LLC, Detroit, MI (US)

(72) Inventors: Jun-Mo Kang, Ann Arbor, MI (US); Jordan Renn, Northville, MI (US)

(73) Assignee: GM GLOBAL TECHNOLOGY OPERATIONS LLC, Detroit, MI (US)

(21) Appl. No.: 19/096,856

(22) Filed: Apr. 1, 2025

(51) Int. Cl. E05B 81/20; E05B 81/06; E05B 81/56; E05B 81/64; H02P 23/12; H02P 23/14; H02P 23/24; H03H 17/02

(52) U.S. Cl. CPC E05B 81/21; E05B 81/06; E05B 81/56; E05B 81/64; H02P 23/12; H02P 23/14; H02P 23/24; H03H 17/0202; H03H 2017/0205

(57) ABSTRACT

A method for an obstacle detection includes pulling a panel towards a body with a motor. The panel is held against the body in a closed condition. The panel is moveable relative to the body while in an open condition. The method includes calculating an angular velocity of the motor based on a current signal through the motor and a voltage signal applied to the motor, calculating a power produced by the motor in response to the current signal and the voltage signal, calculating a real-time parameter in response to the angular velocity and the power, and stopping the motor in response to the real-time parameter relative to a parameter threshold to avoid an obstacle from being pinched between the panel and the body.

### INTRODUCTION

The present disclosure relates to a system and a method for a real-time parameter based obstacle detection.

Cinching latches perform a function of closing panels of vehicles in a last few millimeters before full closure. The cinching latches actuate latch fork bolts and pull on strikers such that the panels are pulled towards bodies of the vehicles. Pressure sensitive pinch sensors along closing edges of the panels determine when obstacles are being pressed by the panels against the vehicle bodies shortly before closure.

Accordingly, those skilled in the art continue with research and development efforts in the field of detection timing and detection techniques for obstacles being pinched between motor closable panels and vehicle bodies.

### SUMMARY

A method for an obstacle detection is provided herein. The method includes pulling a panel towards a body of a vehicle with a motor. A striker or a latch is attached to the panel and is operational to interact with the latch or the striker on the body. The panel is held against the body in a closed condition. The panel is moveable relative to the body while in an open condition. The method includes calculating an angular velocity of the motor based on a current signal through the motor and a voltage signal applied to the motor, calculating a power produced by the motor in response to the current signal and the voltage signal, calculating a real-time parameter in response to the angular velocity and the power, and stopping the motor in response to the real-time parameter relative to a parameter threshold to avoid an obstacle from being pinched between the panel and the body.

In one or more embodiments of the method, the real-time parameter is the angular velocity per the power.

In one or more embodiments of the method, the real-time parameter is the power per the angular velocity.

In one or more embodiments, the method includes calculating a minimum-to-maximum ratio of a real-time parameter trace.

In one or more embodiments, the method includes calculating a peak-to-peak ratio of the minimum-to-maximum ratio, wherein the stopping of the motor is in response to the peak-to-peak ratio relative to a peak-to-peak threshold.

In one or more embodiments of the method, the stopping of the motor is determined in response to the minimum-to-maximum ratio relative to a minimum-to-maximum threshold.

In one or more embodiments, the method includes initiating an obstacle detection technique in response to an angular distance of the motor from an end position relative to a distance threshold.

In one or more embodiments, the method includes commanding the motor to spin in reverse after the motor is stopped to release the obstacle from being pinched.

In one or more embodiments, the method includes commanding the motor to continue to spin forward in response to the real-time parameter relative to the parameter threshold.

A system is provided herein. The system includes a motor and a controller. The motor is operational to pull a panel towards a body. A striker or a latch is attached to the panel and is operational to interact with the latch or the striker on the body. The panel is held against the body in a closed condition. The panel is moveable relative to the body while in an open condition. The controller is operational to calculate an estimated angular velocity of the motor based on a current signal through the motor and a voltage signal applied to the motor, calculate a power produced by the motor in response to the current signal and the voltage signal, calculate a real-time parameter in response to the estimated angular velocity and the power, and stop the motor in response to the real-time parameter relative to a parameter threshold to avoid an obstacle from being pinched between the panel and the body.

In one or more embodiments of the system, the real-time parameter is the angular velocity per the power.

In one or more embodiments of the system, the real-time parameter is the power per the angular velocity.

In one or more embodiments of the system, the controller is further operational to calculate a minimum-to-maximum ratio of a real-time minimum-to-maximum trace.

In one or more embodiments of the system, the controller is further operational to calculate a peak-to-peak ratio of the minimum-to-maximum ratio, wherein the stopping of the motor is in response to the peak-to-peak ratio relative to a peak-to-peak threshold.

In one or more embodiments of the system, the stopping of the motor is determined in response to the minimum-to-maximum ratio relative to a minimum-to-maximum threshold.

In one or more embodiments of the system, the controller is further operational to initiate an obstacle detection technique in response to an angular distance of the motor from an end position relative to a distance threshold.

In one or more embodiments of the system, the controller is further operational to command the motor to spin in reverse after the motor is stopped to release the obstacle from being pinched.

In one or more embodiments of the system, the controller is further operational to command the motor to continue to spin forward in response to the real-time parameter relative to the parameter threshold.

A vehicle is provided herein. The vehicle includes a body, a panel, a striker, a latch, a motor, and a controller. The panel moveably coupled to the body. The striker or the latch is attached to the panel and operational to interact with the latch or the striker attached to the body. The panel is held against the body in a closed condition, and moveable relative to the body while in an open condition. The motor is operational to pull the panel towards the body. The controller is operational to calculate an estimated angular velocity of the motor based on a current signal through the motor and a voltage signal applied to the motor, calculate a power produced by the motor in response to the current signal and the voltage signal, calculate a real-time parameter in response to the estimated angular velocity and the power, and stop the motor in response to the real-time parameter relative to a parameter threshold to avoid an obstacle from being pinched between the panel and the body.

In one or more embodiments of the vehicle, the panel is one of a door, a hood, a sliding door, a decklid, an end gate, a tailgate, a liftgate, a movable partition panel, a sunroof, and a power window.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 is a schematic diagram illustrating a context of a system in accordance with one or more exemplary embodiments.

FIG. 2 is a schematic diagram of a dynamic model of an electric circuit and motor in accordance with one or more exemplary embodiments.

FIG. 3 is a graph of when to trigger an obstacle detection technique in accordance with one or more exemplary embodiments.

FIG. 4 is a graph of an obstacle detection start determination in accordance with one or more exemplary embodiments.

FIG. 5 is a graph of a normalized step time trace used for cross-correlation in accordance with one or more exemplary embodiments.

FIG. 6 is a graph of a final peak-to-peak threshold dependency on a measured force in accordance with one or more exemplary embodiments.

FIG. 7 is a graph of obstacle detection traces during cinching in accordance with one or more exemplary embodiments.

FIG. 8 is a functional flow diagram of a method for calculating a minimum-to-maximum ratio of an angular velocity per motor power in accordance with one or more exemplary embodiments.

FIG. 9 is a flow diagram of a method for detecting an obstacle pinch condition in accordance with one or more exemplary embodiments.

FIG. 10 is a schematic diagram of an operation of a controller in accordance with one or more exemplary embodiments.

FIG. 11 is a flow diagram of another method for detecting an obstacle pinch condition in accordance with one or more exemplary embodiments.

FIG. 12 is a graph of a peak-to-peak threshold dependency on an external force in accordance with one or more exemplary embodiments.

FIG. 13 is a flow diagram of a method for threshold determination centered around an external force prediction in accordance with one or more exemplary embodiments.

### DETAILED DESCRIPTION

Embodiments of the disclosure provide a system and/or method to detect an obstacle for an automotive component driven by electric motor based on given motor current and voltage in a wide variety of applications. The system/method estimates an angular velocity of the motor based on the current and/or voltage of the motor and obtains an angular velocity per motor power in real-time. The peak-to-peak ratio of the real-time parameter is a good indicator to determine an existence of an obstacle. The automotive component may include, but is not limited to, side doors, a hood, and rear closures (e.g., decklid/liftgate). In various embodiments, the system/method provides a real-time strategy to determine when to activate a detection technique to have consistent and robust decision on obstacle detection.

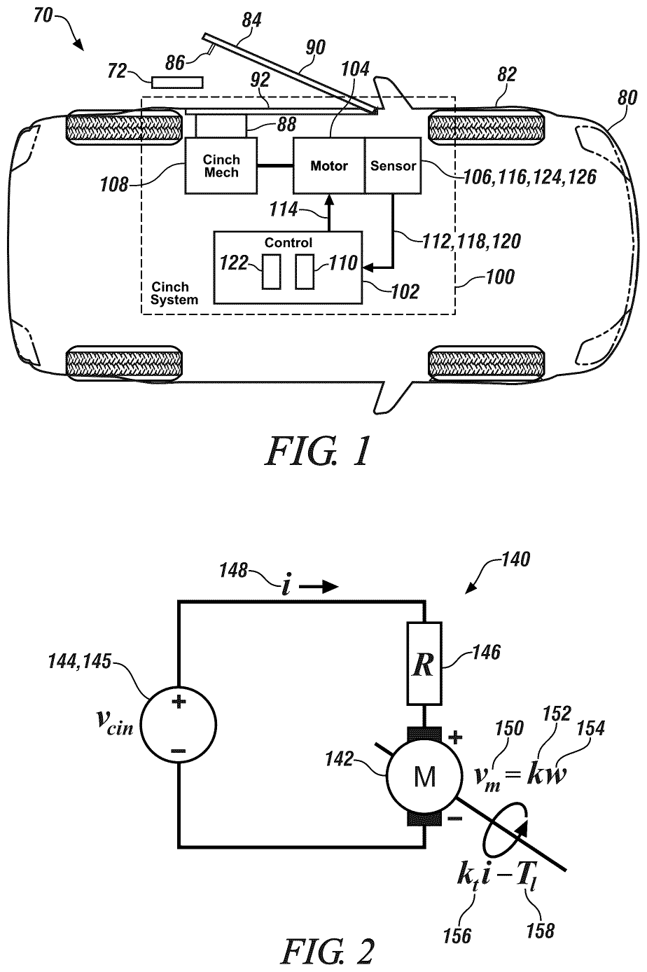

Referring to FIG. 1, a schematic diagram illustrating a context of a system 70 is shown in accordance with one or more exemplary embodiments. The system 70 generally includes an obstacle 72 and a vehicle 80. The vehicle 80 include a body 82, a moveable panel 84, a striker 86 on the moveable panel 84, a latch 88 on the body 82, and a cinch system 100.

The vehicle 80 may include, but is not limited to, mobile objects such as a passenger vehicle, a truck, an autonomous vehicle, an electric-powered vehicle, a hybrid vehicle, a motorcycle, a boat, a farm vehicle, a train and/or an aircraft. In some embodiments, the vehicle 80 may include stationary objects such as lockers, storage facilities and/or buildings. Other types of vehicles 80 may be implemented to meet the design criteria of a particular application.

The body 82 is an outer shell of the vehicle 80. The body 82 generally defines one or more openings that allow people to enter and exit the vehicle and/or access compartments (e.g., an engine compartment) of the vehicle 80. The openings may include, but are not limited to doors, a hood, a sliding door, a decklid, an end gate, a tailgate, a liftgate, a movable partition panel, a sunroof and a power window. Other openings may be implemented to meet the design criteria of a particular application.

The panel 84 is a moveable panel that is aligned with a respective opening. The panel 84 is coupled to the body 82 and moveable between an open condition 90 and a closed condition 92. While in the closed condition 92, the panel 84 is generally in contact with and held against the body 82 of the vehicle 80.

The striker 86 is operable to alternatively engage and disengage from the latch 88 and the cinch system 100. While in the open condition 90, the striker 86 is physically separated from the latch 88 and the cinch system 100. Near the closed condition 92, the striker 86 may engage the cinch system 100. In the closed condition 92, the striker 86 is engaged with the latch 88. In various embodiments, the striker 86 is attached to the panel 84 and the latch 88 is attached to the body 82. In other embodiments, the striker 86 and the latch 88 may be swapped such that the latch 88 is attached to the panel 84 and the striker 86 is attached to the body 82.

The cinch system 100 generally includes a controller 102, a motor 104, an angular sensor 106, a cinch mechanism 108, a current sensor 124, and a voltage sensor 126. An obstacle detection technique 110 may be implemented in software (or code, or instructions) executed by the controller 102. The cinch system 100 is operational to engage the striker 86 and pull the striker 86 into contact with the latch 88. The cinch system 100 is operational to pull the panel 84 from the open condition 90 toward the closed condition 92, determine when to start the obstacle detection technique 110, and either (i) pull the panel 84 into contact with the body 82 at the closed condition 92 or (ii) detect the obstacle 72 becoming pinched between the panel 84 and the body 82, stop the pulling, and push the panel 84 away from the body 82 to release the obstacle 72.

The controller 102 implements multiple digital computation circuits. The digital computation circuits may be implemented in hardware, software executing on hardware, or a combination of both. The controller 102 may receive angular motor information in an angle signal 112 from the angular sensor 106 and present motor control signals 114 to the motor 104. The motor control signals 114 include a desired voltage signal that is applied to the motor 104. The controller 102 also uses motor curve data 122 to control the motor 104. The controller 102 is operational to determine when to start the obstacle detection technique 110.

In various embodiments, the controller generally includes at least one microcontroller. The at least one microcontroller may include one or more processors, each of which may be embodied as a separate processor, an application specific integrated circuit (ASIC), a field programmable gate array (FPGA), or a dedicated electronic control unit. The at least one microcontroller may be an electronic processor (implemented in hardware, software executing on hardware, or a combination of both). The at least one microcontroller may also include tangible, non-transitory memory, (e.g., read-only memory in the form of optical, magnetic, and/or flash memory). For example, the at least one microcontroller may include application-suitable amounts of random-access memory, read-only memory, flash memory and other types of electrically-erasable programmable read-only memory, as well as accompanying hardware in the form of a high-speed clock or timer, analog-to-digital and digital-to-analog circuitry, and input/output circuitry and devices, as well as appropriate signal conditioning and buffer circuitry.

Computer-readable and executable instructions embodying the present method may be recorded (or stored) in the memory and executed as set forth herein. The executable instructions may be a series of instructions employed to run applications on the at least one microcontroller (either in the foreground or background). The at least one microcontroller may receive commands and information, in the form of one or more input signals from various controls or components and communicate instructions to the other electronic components.

The motor 104 is a direct current (DC) motor that drives the cinch mechanism 108 in two directions. The motor 104 is controlled by the controller 102 through the motor control signals 114.

The angular sensor 106 is a sensor that measures an angle of the motor 104 relative to an end position 116 (e.g., a home position or a final position). The measured angle is presented to the controller 102 in an angle signal 112.

The current sensor 124 is a sensor that measures current that flows through the motor 104. The sensed current is presented to the controller 102 in a current signal 118.

The voltage sensor 126 is a sensor that measures the voltage that applied to the motor 104. The sensed voltage is presented to the controller 102 in a voltage signal 120.

The cinch mechanism 108 is a mechanism that translates rotational motion received from the motor 104 into linear motion that alternatively pulls in and pushes away the striker 86.

The obstacle detection technique 110 uses the current signal 118 that flows through the motor 104, the voltage signal 120 that is applied to the motor 104, and the motor curve data 122 to determine when the obstacle 72 is becoming pinched between the closing panel 84 and the body 82 of the vehicle 80.

Referring to FIG. 2, a schematic diagram of an example dynamic model 140 of an electric circuit and motor is shown in accordance with one or more exemplary embodiments. The dynamic model 140 includes a motor 142 (M), a voltage source 145, and a motor resistance 146 (R). A voltage signal 144 is generated by the voltage source 145. The voltage signal 144 establishes a current signal 148 (I) through the motor 142. A voltage 150 (Vm) across the motor 142 due to a back electromagnetic (EMF) force is a product of a back EMF constant 152 (k) and an angular velocity 154 (ω) of the motor 142. The motor 142 produces a motor torque 156 (kₜI), where kₜ is a torque constant. The useable torque may be the motor torque 156 minus a load torque 158 (Tₗ). The dynamic model 140 of the motor 142 may be representative of and apply to the motor 104 (FIG. 1).

Operation of the dynamic model 140 may be expressed by equations 1, 2 and 3 as follows:

$$\frac{d}{d t} [ \begin{matrix}ω ( t ) \\ {T}_{l} ( t )\end{matrix} ] = [ \begin{matrix}- \frac{1}{J} ( \frac{k {k}_{t}}{R} ) & - \frac{1}{J} \\ 0 & 0\end{matrix} ] [ \begin{matrix}ω ( t ) \\ {T}_{l} ( t )\end{matrix} ] + [ \begin{matrix}\frac{{k}_{t}}{J R} \\ 0\end{matrix} ] V cin ( t ) \qquad Eq . ( 1 )$$

$$i ( t ) = [ \begin{matrix}- \frac{k}{R} & 0\end{matrix} ] [ \begin{matrix}ω ( t ) \\ {T}_{l} ( t )\end{matrix} ] + \frac{1}{R} V c i n ( t ) \qquad Eq . ( 2 )$$

$$ω ( t ) = \frac{R}{k} ( V c i n ( t ) / R - i ( t ) ) \qquad Eq . ( 3 )$$

Where J is a moment of inertia and k is a back EMF constant.

The motor parameters R, k, k_{τ} and J are usually found in data sheets from the motor manufacturers. Typical motor parameters of the motor 142 are:

$$Vm = k ω ;$$

$$Tq = {k}_{t} I ;$$

$$K = 0.00025 volts / degrees / second ;$$

$$Kt = 0.012 Nm / A ;$$

$$Vm = 3 volts ; and$$

$$R = 1.2 ohms .$$

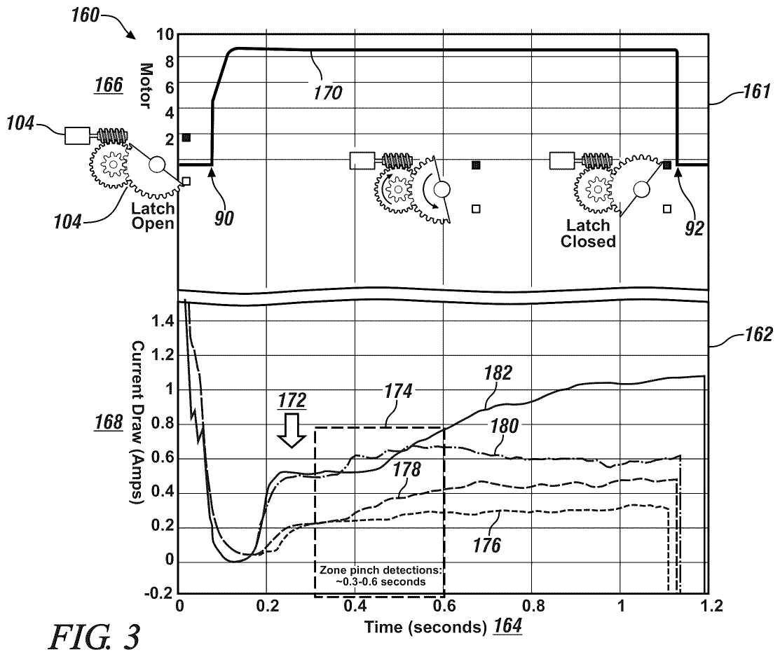

Referring to FIG. 3, a graph 160 of an example of when to trigger the obstacle detection technique is shown in accordance with one or more exemplary embodiments. A top subgraph 161 illustrates the action of the motor 104 and the cinch mechanism 108 over time when a voltage signal is applied. The action ranges from the open condition 90 to the closed condition 92 with no obstacle. A bottom subgraph 162 illustrates the current signal draw of the motor 104 over the same time at two different temperatures and with/without encountering an obstacle. An X-axis 164 of the subgraphs 161 and 162 are in units of second. The Y-axis 166 of the subgraph 161 is in units of volts. The Y-axis 168 of the subgraph 162 is in units of amperes.

A voltage signal 170 illustrates the voltage applied to the motor 104. At approximately a time 172 (e.g., 0.25 seconds) after starting, an actual cinch engagement between the striker and the cinch mechanism may begin. A zone 174 for starting the obstacle detection technique generally occurs in a range (e.g., approximately 0.3 second to approximately 0.6 seconds). A curve 176 illustrates an example current draw at +80 degrees Celsius (° C.) with no obstacle. A curve 178 illustrates an example current draw at +80° C. with an obstacle encountered at approximately 0.4 seconds. A curve 180 illustrates an example current draw at −30° C. with no obstacle. A curve 180 illustrates an example current draw at −30° C. with an obstacle encountered at approximately 0.4 seconds. The position and length of the zone 174 may vary depending on temperature, voltage, current, vehicle aging, and the like.

In one or more embodiments, the obstacle detection technique may begin at approximately the time 172 when the actual cinch engagement begins. Triggering the obstacle detection technique may be calibrated per operating conditions.

In other embodiments, the detection begins after the cinch is engaged. To confirm engagement, the obstacle detection begins in response to an angular distance of the motor 104 relative to the end position passes a pre-determined distance threshold (or fixed distance). The angular distance may be measured by the angular sensor 106 (FIG. 1) or by integrating the angular velocity @ over time. For example, the angular distance may be calculated per equation 4 as follows:

$$Angular distance = \int ω d t \qquad Eq . ( 4 )$$

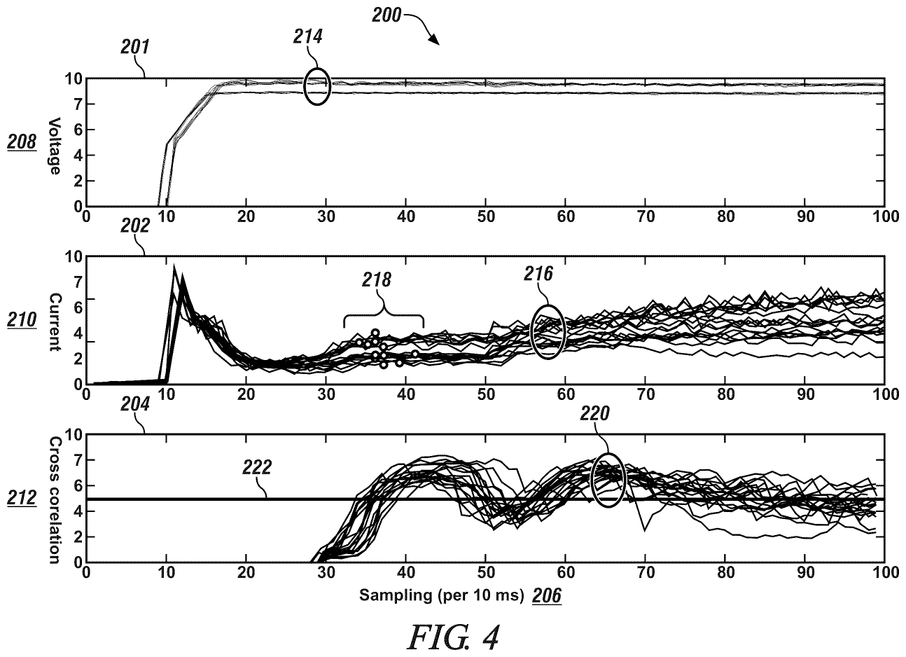

Referring to FIG. 4, a graph 200 of an example obstacle detection start determination is shown in accordance with one or more exemplary embodiments. The graph 200 includes subgraphs 201, 202, and 204. The top subgraph 201 illustrates the voltage signal applied to the motor 104 (FIG. 1) over multiple samples. The middle subgraph 202 illustrates the current signal through the motor over the multiple samples. The bottom subgraph 204 illustrates a cross-correlation of the voltage signal to the current signal. An X-axis 206 of the subgraphs 201, 202 and 204 are in units of sampling per 10 milliseconds. The Y-axis 208 of the subgraph 201 is in units of volts. The Y-axis 210 of the subgraph 202 is in units of amperes. The Y-axis 212 of the subgraph 204 is in units of a cross-correlation value.

Traces 214 illustrate multiple overlaid voltage signal samples. Traces 216 illustrate multiple overlaid current signal samples. The cinch engagement (or closing status) is detected in a window 218 using the cross-correlation. Traces 220 illustrate multiple overlaid cross-correlation values traces. A correlation threshold 222 is used as a detection threshold for the cross-correlation value traces 220. When the cross-correlation value traces 220 reach the correlation threshold 222, a sufficient similarity of the current signal samples and the voltage signal samples exist to indicate that the obstacle detection technique may be started.

In various embodiments, a pinch may be determined based on the peak-to-peak ratio of a minimum-to-maximum ratio of the angular velocity per motor power (ω/P) or motor power per angular velocity (P/ω) relative to the peak-to-peak threshold. In other embodiments, the pinch may be determined if the peak-to-peak ratio of a minimum-to-maximum ratio of the inverse load torque is less than the peak-to-peak threshold.

The voltage signal 144 received by the motor 104 (FIG. 1) is controlled via an open-loop arrangement to regulate and remain constant during the cinching process. When the load torque on the motor 104 increases (e.g., due to the obstacle 72 in FIG. 1), the angular velocity ω decreases, which results in an increase in the current signal, thus, the motor torque as well. When the current signal increases, the power quadratically increases. Therefore, the angular velocity per motor power ω/P or the motor power per angular velocity P/ω are sensitive to detect the obstacle 72.

The subgraph 202 shows a typical time trace of current to the motor 104. At approximately time 0.1 sec, the motor 104 begins to spin overcoming static friction through sufficient current provided. The current quickly decreases until the actual latching process begins and thus load to the motor 104 increases at around 0.4 seconds (e.g., in the window 218). Depending on operating conditions, the time when latching process begins may vary so does the t₀ when the peak-to-peak ratio ζ_{p/p} begins to be recorded in real time for obstacle detection. Since the trace of the peak-to-peak ratio ζ_{p/p} is sensitive to the time t₀, it is also deemed that precisely detecting the time when latching process begins is helpful for robust obstacle detection performance.

The figure shows that the beginning of the latching process is characterized by a first sudden increment of current after the motor spins. As such, a step time trace of finite length is introduced for cross-correlation with the current to detect the time when latching process begins. Since detecting solely a first step-like current pattern is interested, both the step time trace and a buffer of past current time traces are normalized from zero to one to maximize sensitivity.

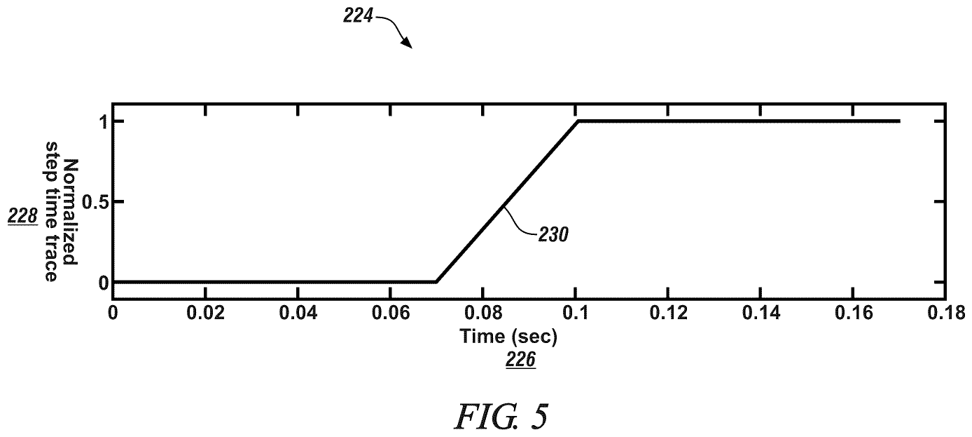

Referring to FIG. 5, a graph of an example normalized step time trace used for cross-correlation is shown in accordance with one or more exemplary embodiments. The graph 224 includes an X-axis 226 in units of seconds. A Y-axis 228 shows a normalized range from 0 to 1. A curve 230 illustrates a step time trace for cross-correlation.

The cross-correlation may be obtained using two normalized time traces per equation 5 as follows,

$$( s * i ) ( t ) = {\sum }_{j = 1}^{m} s ( j ) i ( j + t ) , \qquad Eq . ( 5 )$$

Where s is the step time trace, m is the length of the step time trace s.

The subgraphs 202 and 204 in FIG. 4 show the beginning time t₀ of the latching process detected using cross-correlations with the current trace in various operating conditions when the normalized step time trace in FIG. 5 is used. The latching process begins if the cross-correlation in subgraph 204 is higher than the threshold 222, where the threshold is set to be 5 in the example.

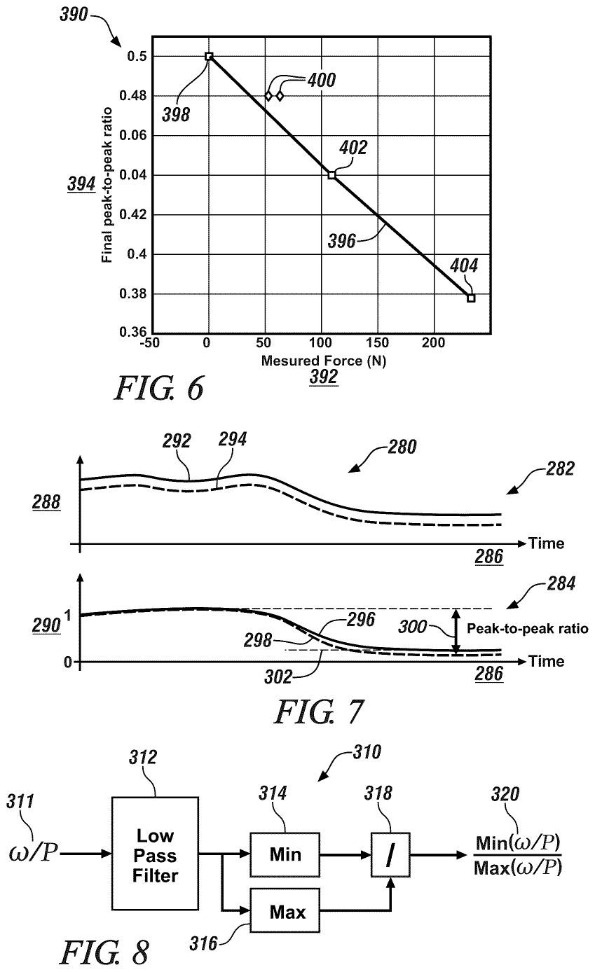

Referring to FIG. 6, a graph 390 of an example final peak-to-peak threshold dependency on a measured external force is shown in accordance with one or more exemplary embodiments. The graph 390 has an X-axis 392 illustrating a measured force in Newtons (N). A Y-axis 394 of the graph 390 illustrates a final peak-to-peak ratio.

To achieve consistent and subjective detection performance, a peak-to-peak threshold may be calibrated to have a good correlation with the actual force on the obstacle 72. The maximum force on various obstacles may be experimentally measured in the lab and correlated with the corresponding peak-to-peak ratio at the end of the latching process.

A line 396 illustrate the final peak-to-peak ratio over a range of forces from zero force (e.g., no obstacle) at a point 398 to a hard obstacle at a point 404. Intermediate points include to forces measured with the peak-to-peak threshold set to 0.48 at points 400 and a soft obstacle at a point 402.

Referring to FIG. 7, a graph 280 of an example obstacle detection traces of the angular velocity per motor power (ω/P) during cinching is shown in accordance with one or more exemplary embodiments. The graph 280 includes a subgraph 282 and a subgraph 284. An X-axis 286 of the subgraphs 282 and 284 illustrate time. The Y-axis 288 of the subgraph 282 illustrates amplitude. The Y-axis 290 of the subgraph 284 illustrates the peak-to-peak ratio of a minimum-to-maximum ratio of the angular velocity per motor power (ω/P).

In the subgraph 282, traces 292 and 294 illustrate the angular velocity per motor power (ω/P) over time with two different operating conditions when an obstacle exists. The angular velocity per motor power (ω/P) trace may vary depending on the voltage signal, temperature, gaining, and the like, resulting in variations in nominal angular velocity per motor power. Therefore, real-time tracking of the peak-to-peak ratio of the minimum and maximum values of the angular velocity per motor power (ω/P) trace may be used to detect an obstacle.

In the subgraph 284, traces 296 and 298 illustrate a peak-to-peak ratio of minimum-to-maximum trace of the angular velocity per motor power over time, respectively. If the traces of peak-to-peak ratio 300 is less than a peak-to-peak threshold 302, an obstacle has been detected.

Referring to FIG. 8, a functional flow diagram of an example method 310 for calculating a minimum-to-maximum ratio of the angular velocity per motor power is shown in accordance with one or more exemplary embodiments. The method (or process) 310 includes steps 312 to 318, as illustrated. The sequence of steps is shown as a representative example. Other step orders may be implemented to meet the criteria of a particular application.

In the step 312 a low pass filtering is performed on the angular velocity per motor power trace 311. Minimum values of the low-pass filtered trace are determined in the step 314. Maximum values of the low-pass filtered trace are determined in the step 316. A ratio of the minimum values per the maximum values are calculated in the step 318 to produce the minimum-to-maximum ratio trace 320.

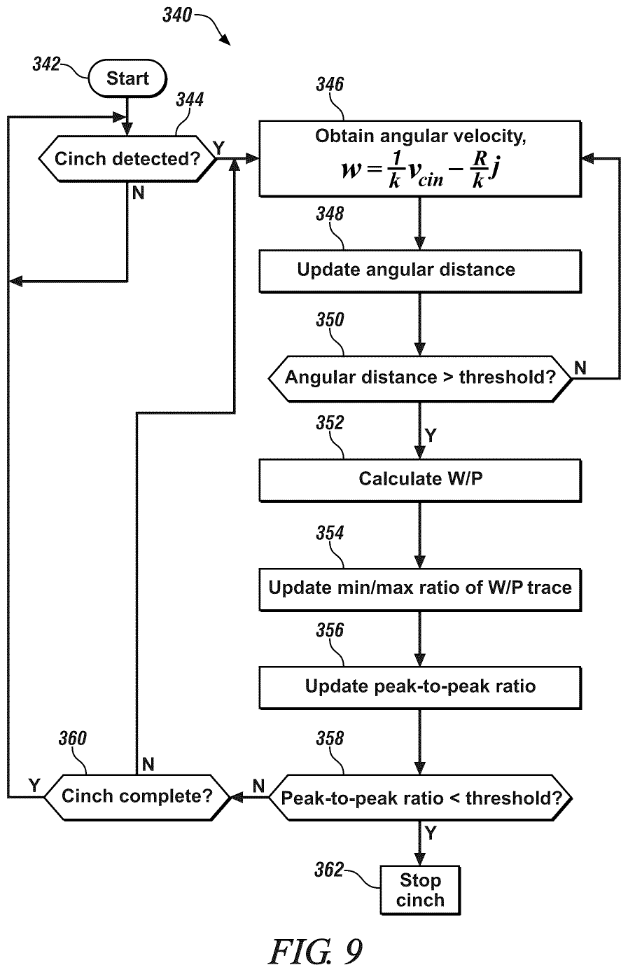

Referring to FIG. 9, a flow diagram of an example method 340 for detecting an obstacle pinch condition is shown in accordance with one or more exemplary embodiments. The method (or process) 340 generally includes steps 342 to 362, as illustrated. The sequence of steps is shown as a representative example. Other step orders may be implemented to meet the criteria of a particular application. The method 340 is implemented by the cinch system 100.

The method 340 starts in the step 342. In decision step 344, a check is made to see if the start of a cinch has been detected. If no cinch has been detected, the method 340 returns to a beginning of the decision step 344 and checks again. Once a cinch has been detected in the decision step 344, the method 340 continues with the step 346.

In the step 346, the controller 102 calculates the angular velocity of the motor. In the step 348, the angular distance is updated in time. A check is performed in the decision step 350 to compare the angular distance with a distance threshold. If the angular distance is less than or matches the distance threshold, the method 340 returns to the step 346 to re-estimate the angular velocity. Once the angular distance exceeds the distance threshold, an estimate of the angular velocity per motor power is calculated in the step 352.

In the step 354, a trace of a minimum-to-maximum ratio of the angular velocity per motor power is updated. The peak-to-peak ratio of the minimum-to-maximum ratio is updated in the step 356. In decision step 358, the peak-to-peak ratio is compared to a peak-to-peak threshold. If the peak-to-peak ratio matches or is greater than the peak-to-peak threshold, a check is performed in the decision step 360 to determine if the cinch operation has completed. If the cinch operation has been completed, the method 340 returns to the step 344 and waits for the next cinch to be detected. If the cinch is not complete the method 340 returns to the step 346 to calculate the angular velocity another time. When the peak-to-peak ratio falls below the peak-to-peak threshold per the decision step 358, the cinch operation is stopped in the step 362. Per equation 6:

$$P = ω \times T \qquad Eq . ( 6 )$$

Furthermore, equation 7 is true:

$$\frac{ω}{P} = \frac{1}{motor torque} \qquad Eq . ( 7 )$$

Therefore, the angular velocity per motor power (ω/P) may also be determined by equation 8 as follows:

$$\frac{ω}{P} = \frac{1}{{k}_{t} I} \qquad Eq . ( 8 )$$

As such, the angular velocity per motor power ω/P may be directly estimated if the motor torque or the load torque (Tₗ) is available as the moment of inertia of motor 104 is small.

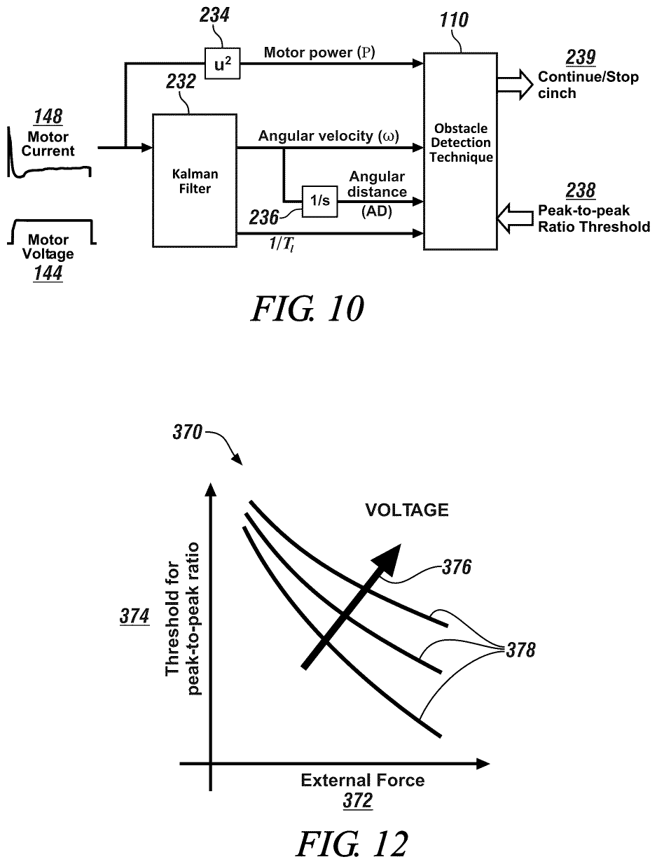

Referring to FIG. 10, a schematic diagram of an example operation of the controller 102 is shown in accordance with one or more exemplary embodiments. The controller 102 may include a filter 232, a converter 234, an integrator 236, and the obstacle detection technique 110.

The current signal 148 and the voltage signal 144 for the motor 104 are received by the filter 232. The filter 232 generates the angular velocity ω and the load torque (Tₗ). The filter 232 may be a Kalman filter or other dynamic observer. The current signal 148 is received by the converter 234 to obtain motor power.

The integrator 236 generates the angular distance (AD) of the motor 104 by integrating the angular velocity (see equation 4). The obstacle detection technique 110 receives the motor power P, the angular velocity ω, the angular distance AD, the inverse load torque 1/Tₗ, a ratio threshold 238 for a peak-to-peak ratio. A status signal 239 may be generated and presented by the obstacle detection technique 110. The status signal 239 may be to continue the cinch because no obstacle 72 (FIG. 1) has been detected, or stop the cinch because the obstacle 72 was detected.

Referring to FIG. 11, a flow diagram of another example method 240 for detecting an obstacle pinch condition is shown in accordance with one or more exemplary embodiments. The method (or process) 240 generally includes steps 242 to 262, as illustrated. The sequence of steps is shown as a representative example. Other step orders may be implemented to meet the criteria of a particular application. The method 240 is implemented by the cinch system 100.

The method 240 starts in the step 242. In decision step 244, a check is made to see if the start of a cinch has been detected. If no cinch has been detected, the method 240 returns to a beginning of the decision step 244 and checks again. Once a cinch has been detected in the decision step 244, the method 240 continues with the step 246.

In the step 246, the controller 102 runs an observer (e.g., the Kalman filter) to estimate the angular velocity and the load torque on the motor. In the step 248, the angular distance is updated in time. A check is performed in the decision step 250 to compare the angular distance with a distance threshold. If the angular distance is less than or matches the distance threshold, the method 240 returns to the step 246 to re-estimate the angular velocity and the load torque. Once the angular distance exceeds the distance threshold, an estimate of the inverse load torque (1/Tₗ) is calculated in the step 252.

In the step 254, a trace of a minimum-to-maximum ratio of the inverse load torque is updated. The peak-to-peak ratio of the minimum-to-maximum ratio is updated in the step 256. In decision step 258, the peak-to-peak ratio is compared to a peak-to-peak threshold. If the peak-to-peak ratio matches or is greater than the peak-to-peak threshold, a check is performed in the decision step 260 to determine if the cinch operation has completed. If the cinch operation has been completed, the method 240 returns to the step 244 and waits for the next cinch to be detected. If the cinch is not complete the method 240 returns to the step 246 to run the observer another time. When the peak-to-peak ratio falls below the peak-to-peak threshold per the decision step 258, the cinch operation is stopped in the step 262.

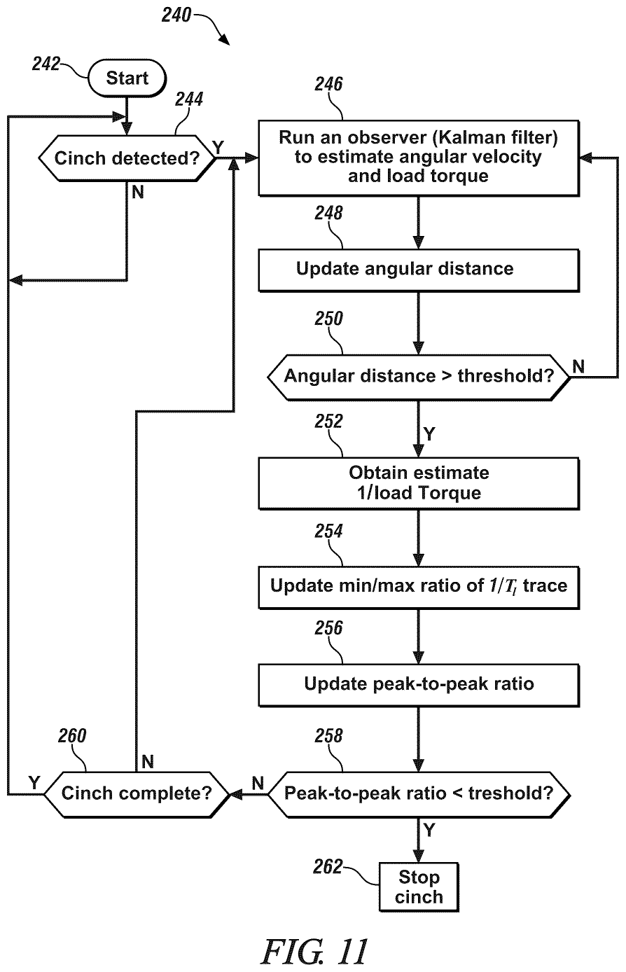

Referring to FIG. 12, a graph 370 of an example peak-to-peak threshold dependency on an external force is shown in accordance with one or more exemplary embodiments. The graph 370 has an X-axis 372 illustrating an external force on the cinch mechanism 108. A Y-axis 374 of the graph 370 illustrates a peak-to-peak threshold for the peak-to-peak ratio.

Given a desired cinch voltage 376, the peak-to-peak threshold 378 decreases if the external force (e.g., a load torque on the motor due to an obstacle interfering with the panel closing) threshold increases. Given an external force threshold (or a given load torque due to the obstacle), the peak-to-peak threshold 378 decreases if the cinch voltage 376 increases.

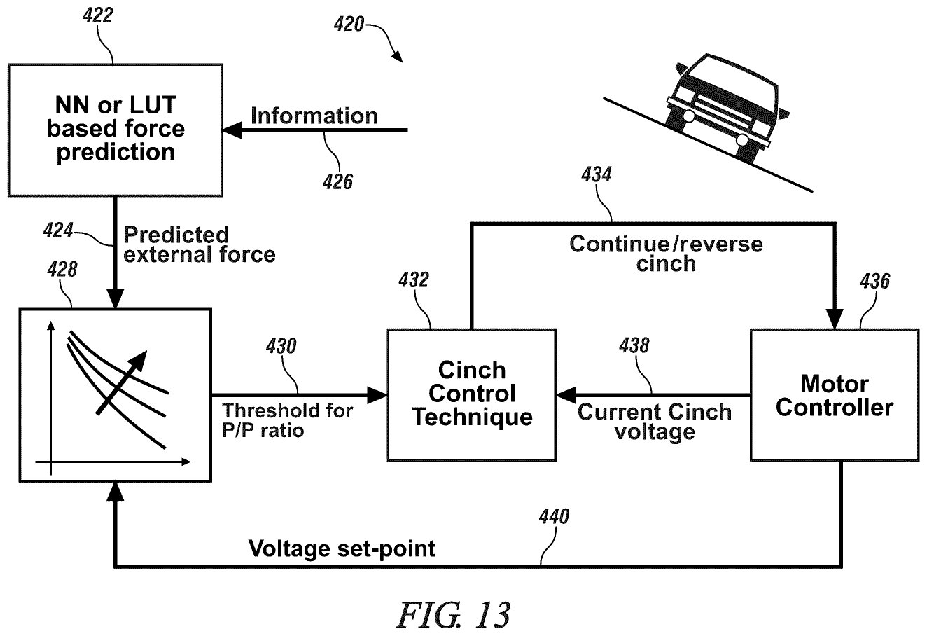

Referring to FIG. 13, a flow diagram of an example method 420 for threshold determination centered around an external force prediction is shown in accordance with one or more exemplary embodiments. The method (or process) 420 includes steps 422 to 438, as illustrated. The method 420 may be performed in a test facility. The method 420 uses an external force as an independent variable to determine the peak-to-peak threshold. The method 420 provides a systematic, two-step calibration method to reduce calibration time and effort.

In the step 422 a neural network (NN) or lookup table (LUT)-based force prediction may predict an external force 424 on a panel (e.g., door) of a vehicle 80. The prediction is calibrated per vehicle model. External forces applied to the panel generally change per aging of the door sealing, pitch and/or roll angle of the vehicle, ambient temperature, and the like. Therefore, prediction performed in the step 422 may be based on information 426. The information 426 may include, but is not limited to the pith angle, the roll angle, the door position (e.g., left or right), aging information, and ambient temperature.

In the step 428, the threshold for a peak-to-peak ratio as a function of external force (e.g., the graph 370 in FIG. 12) determination may use the predicted external force 424 to determine the peak-to-peak threshold for the peak-to-peak ratio 430. In the step 432, a cinch control technique is used to decide if the cinch should be continued or stopped and reversed 434. The controller of the motor provides the current signal and the voltage signal 438 back to the cinch control technique 432 in the step 436. In step 436, the motor controller also determines a voltage set-point 440 that is feed back to the step 428.

The system and/or method calculates an angular velocity per power of a motor in real-time. A peak-to-peak ratio of the real-time parameter is used to determine an existence of an obstacle between the panel and a body of a vehicle. In one or more embodiments, activation timing of the detection may be determined using cross-correlation function.

Embodiments of the disclosure generally provide a method for an obstacle detection that includes pulling a panel towards a body of a vehicle with a motor. A striker/latch is attached to the panel and is operational to interact with the latch/striker on the body. The panel is held against the body in a closed condition, and moveable relative to the body while in an open condition. The method includes calculating an angular velocity of the motor based on a current signal through the motor and a voltage signal applied to the motor, calculating a power produced by the motor in response to the current signal and the voltage signal, calculating a real-time parameter in response to the angular velocity and the power, and stopping the motor in response to the real-time parameter relative to a parameter threshold to avoid an obstacle from being pinched between the panel and the body.

Numerical values of parameters (e.g., of quantities or conditions) in this specification, including the appended claims, are to be understood as being modified in each instance by the term “about” whether or not “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of values and further divided ranges within the entire range. Each value within a range and the endpoints of a range are hereby disclosed as a separate embodiment.

While the best modes for carrying out the disclosure have been described in detail, those familiar with the art to which this disclosure relates will recognize various alternative designs and embodiments for practicing the disclosure within the scope of the appended claims.

What is claimed is:

1. A method for an obstacle detection comprising:
pulling a panel towards a body of a vehicle with a motor, wherein:
a striker or a latch is attached to the panel and is operational to interact with the latch or the striker on the body;
the panel is held against the body in a closed condition; and
the panel is moveable relative to the body while in an open condition;
calculating an angular velocity of the motor based on a current signal through the motor and a voltage signal applied to the motor;
calculating a power produced by the motor in response to the current signal and the voltage signal;
calculating a real-time parameter in response to the angular velocity and the power; and
stopping the motor in response to the real-time parameter relative to a parameter threshold to avoid an obstacle from being pinched between the panel and the body.

2. The method according to claim 1, wherein:
the real-time parameter is the angular velocity per the power.

3. The method according to claim 1, wherein:
the real-time parameter is the power per the angular velocity.

4. The method according to claim 2, further comprising:
calculating a minimum-to-maximum ratio of a real-time parameter trace.

5. The method according to claim 4, further comprising:
calculating a peak-to-peak ratio of the minimum-to-maximum ratio, wherein the stopping of the motor is in response to the peak-to-peak ratio relative to a peak-to-peak threshold.

6. The method according to claim 4, wherein:
the stopping of the motor is determined in response to the minimum-to-maximum ratio relative to a minimum-to-maximum threshold.

7. The method according to claim 4, further comprising:
initiating an obstacle detection technique in response to an angular distance of the motor from an end position relative to a distance threshold.

8. The method according to claim 7, further comprising:
commanding the motor to spin in reverse after the motor is stopped to release the obstacle from being pinched.

9. The method according to claim 8, further comprising:
commanding the motor to continue to spin forward in response to the real-time parameter relative to the parameter threshold.

10. A system comprising:
a motor operational to pull a panel towards a body; wherein:
a striker or a latch is attached to the panel and is operational to interact with the latch or the striker on the body;
the panel is held against the body in a closed condition; and
the panel is moveable relative to the body while in an open condition; and
a controller operational to:
calculate an estimated angular velocity of the motor based on a current signal through the motor and a voltage signal applied to the motor;
calculate a power produced by the motor in response to the current signal and the voltage signal;
calculate a real-time parameter in response to the estimated angular velocity and the power; and
stop the motor in response to the real-time parameter relative to a parameter threshold to avoid an obstacle from being pinched between the panel and the body.

11. The system according to claim 10, wherein:
the real-time parameter is the angular velocity per the power.

12. The system according to claim 10, wherein:
the real-time parameter is the power per the angular velocity.

13. The system according to claim 11, wherein the controller is further operational to:
calculate a minimum-to-maximum ratio of a real-time minimum-to-maximum trace.

14. The system according to claim 13, wherein the controller is further operational to:
calculate a peak-to-peak ratio of the minimum-to-maximum ratio, wherein the stopping of the motor is in response to the peak-to-peak ratio relative to a peak-to-peak threshold.

15. The system according to claim 14, wherein:
the stopping of the motor is determined in response to the minimum-to-maximum ratio relative to a minimum-to-maximum threshold.

16. The system according to claim 13, wherein the controller is further operational to:
initiate an obstacle detection technique in response to an angular distance of the motor from an end position relative to a distance threshold.

17. The system according to claim 16, wherein the controller is further operational to:
command the motor to spin in reverse after the motor is stopped to release the obstacle from being pinched.

18. The system according to claim 17, wherein the controller is further operational to:
command the motor to continue to spin forward in response to the real-time parameter relative to the parameter threshold.

19. A vehicle comprising:
a body;
a panel moveably coupled to the body;
a striker or a latch attached to the panel and operational to interact with the latch or the striker attached to the body, wherein the panel is:
held against the body in a closed condition; and
moveable relative to the body while in an open condition;
a motor operational to pull the panel towards the body; and
a controller operational to:
calculate an estimated angular velocity of the motor based on a current signal through the motor and a voltage signal applied to the motor;
calculate a power produced by the motor in response to the current signal and the voltage signal;
calculate a real-time parameter in response to the estimated angular velocity and the power; and
stop the motor in response to the real-time parameter relative to a parameter threshold to avoid an obstacle from being pinched between the panel and the body.

20. The vehicle according to claim 19, wherein the panel is one of a door, a hood, a sliding door, a decklid, an end gate, a tailgate, a liftgate, a movable partition panel, a sunroof, and a power window.
